(19) United States
(12) Patent Application Publication
(10) Pub. No.: US 2002/0061635 A1
(43) Pub. Date: May 23, 2002

(54) Solution for chemical mechanical polishing and method of manufacturing copper metal interconnection layer using the same

(75) Inventors: Jong-won Lee, Sungnam City (KR); Bo-Un Yoon, Seoul (KR); Sang-rok Hah, Seoul (KR)

Correspondence Address: Frank Chau, F. CHAU & ASSOCIATES, LLP, Suite 501, 1900 Hempstead Turnpike, East Meadow, NY, 11554, US

(73) Assignee: Samsung Electronics Co., Ltd.

(21) Appl. No.: 09/899,627

(22) Filed: Jul. 5, 2001

(30) Foreign Application Priority Data
Nov. 23, 2000 (KR) 2000-70008

(51) Int. Cl. H01L 21/20

(52) U.S. Cl. 438/584

(57) ABSTRACT

A solution used for chemical mechanical polishing of a copper metal interconnection layer and a method of manufacturing a copper metal interconnection layer using the solution are provided. The method of manufacturing the copper metal interconnection layer includes the steps of forming a barrier layer along a stepped portion over the surface of the interdielectric layer having a recessed region; forming a copper seed layer along a stepped portion on the barrier layer, and exposing the barrier layer until exposing the surface of the interdielectric layer by chemical mechanical polishing using the solution including an oxidizing agent, a pH controlling agent, a chelate reagent, and deionized water. The oxidizing agent is hydrogen peroxide (H₂O₂), an oxidizing agent of a ferric series, or an oxidizing agent of an ammonium series. The pH controlling agent is an acidic or a basic solution. The chelate reagent is diammonium sodium salt (DASS), citric acid, malic acid, gluconic acid, gallic acid, tannic acid, ethylenediaminetetraacetic (EDTA) or benzotriazole (BTA).

### BACKGROUND OF THE INVENTION

1. Field of the Invention

The present invention relates to a solution for chemical mechanical polishing (CMP) of semiconductor device, and more particularly to a solution composition and a method for CMP plananarizing of copper metal interconnection layer.

2. Discussion of Related Art

As semiconductor devices become highly efficient and highly integrated, multi-layered interconnection layers are used in the design and manufacturing processes. In a multi-layered interconnection layer, such as a layer formed from an insulating layer and from deposition of metal interconnections, a CMP process is performed for planarizing a base layer to more easily perform subsequent processes such as photolithography.

To enhance polishing operation efficiency, a slurry solution for the CMP process may be used. Generally, the CMP process applies combining chemical effects of chemical solutions with mechanical effects of a polisher and polishing particles. When a wafer surface contacts a pad, a slurry for CMP process flows into a minute gap between the contact surfaces of the wafer and the pad, so that a mechanical operation is performed by abrasive particles within the slurry and bumps on the surface of the pad, and a chemical removing operation is performed by a chemical component within the slurry.

In forming a semiconductor interconnection layer, it is important to reduce the resistance and capacitance (RC) value of a semiconductor device by having low resistance and low parasitic capacitance. Copper (Cu) has a lower resistivity than aluminum (Al) and therefore is preferred conductive material for use in a metal interconnection process to reduce interconnection resistance and parasitic capacitance. The RC reduction is more important as a semiconductor design rule becomes less than 0.18 μm.

A metal interconnection layer using aluminum is formed by a photolithography process: i.e., first, a metal interconnection material is coated on the substrate and then the metal interconnection material is patterned. However, a metal interconnection layer using copper is usually formed differently because of difficulties in the patterning process. That is, a metal interconnection region is formed within an interdielectric layer on the substrate, then the metal interconnection material is buried in the metal interconnection region.

FIG. 1 is a sectional view illustrating a copper seed layer having abrasives as a contaminant after CMP process using a conventional slurry. Referring to FIG. 1, a barrier layer 14 is formed along a stepped portion of an inter-dielectirc layer 10 having trenches 12. Copper is deposited on the barrier layer 14 using a physical vapor deposition (PVD) such as sputtering and a copper seed layer is formed on the stepped portion of copper. And then, chemical mechanical polishing (CMP) is performed using a conventional slurry to polish and remove the upper copper seed layers 16 until exposing the barrier layer 14 so that copper seed layers 16 are formed in the trenches 12, The conventional slurry for CMP has an abrasive such as alumina or silica, the abrasive may be left on the copper seed layer in the trench after CMP process. The remaining abrasive in the trench may not easily be removed by cleaning. As the integration density of the semiconductor devices increases, the remaining abrasive in the trench may cause not only contamination of the wafer but also may scratch the wafer, and more seriously, lifting of the metal interconnection.

### SUMMARY OF THE INVENTION

A solution for use in a chemical mechanical polishing (CMP) process of a copper metal interconnection layer is provided. The solution includes an oxidizing agent, a pH controlling agent, a chelate reagent, and deionized water. Preferably, the solution does not include an abrasive.

According to an aspect of the invention, the oxidizing agent is preferably a hydrogen peroxide, an oxidizing agent of a ferric series or an oxidizing agent of an ammonium series. The concentration of hydrogen peroxide is within the range of about 1% to about 20% by weight. The concentration of the oxidizing agent of the ferric series is within the range of about 0.01% to about 5% by weight. The concentration of the oxidizing agent of the ammonium series is within the range of about 0.01% to about 5% by weight.

According to an aspect of the invention, a pH of the solution is within the range of about 2 to about 11 and the pH controlling agent is preferably an acidic or a basic solution. The acidic solution is a sulfuric acid solution, a nitric acid solution, a hydrochloric acid solution or a phosphoric acid solution, and the basic solution is a potassium hydroxide solution or an ammonium hydroxide solution.

The chelate reagent is diammonium sodium salt (DASS), citric acid, malic acid, gluconic acid, gallic acid, tannic acid, ethylenediaminetetraacetic (EDTA), or benzotriazole (BTA). And the concentration of the chelate reagent is within the range of about 0.001% to 1% by weight.

A method of manufacturing a copper metal interconnection layer is also provided which includes the steps of: forming a barrier layer along a stepped portion over the surface of the interdielectric layer having a recessed region; forming a copper seed layer on the barrier layer; and exposing the barrier layer until exposing the surface of the interdielectric layer by chemical mechanical polishing using a solution comprising an oxidizing agent, a pH controlling agent, a chelate reagent, and deionized water so that the copper seed layer remains only within the recessed region.

According to an aspect of the invention, after the step of exposing the barrier layer by CMP, the method of manufacturing a copper metal interconnection layer further includes the steps of: forming a copper layer on the copper seed layer formed in the recessed region; and forming a copper metal interconnection layer by planarizing the copper layer projecting above the surface of the interdielectric layer, the copper seed layer projecting above the surface of the interdielectric layer and the barrier layer projecting above the surface of the interdielectric layer.

According to the aspect of the invention, the recessed region includes a combination of a trench region in the shape of a line recessed from the surface of the interdielectric layer, and contact holes or via holes penetrating the interdielectric layer. The barrier layer is formed using a material which can prevent diffusion of metal and act as an adhesive layer between the interdielectric layer and the metal interconnection.

A solution for use in a chemical mechanical polishing process is consisted essentially of an oxidizing agent, a pH controlling agent, a chelate reagent, and deionized water.

### BRIEF DESCRIPTION OF THE DRAWINGS

A better understanding of the present invention can be obtained when the following detailed description of a preferred embodiment is considered in conjunction with the following drawings, in which;

FIG. 1 is a sectional view for illustrating a copper seed layer including contaminant abrasives after CMP process using a conventional slurry; and

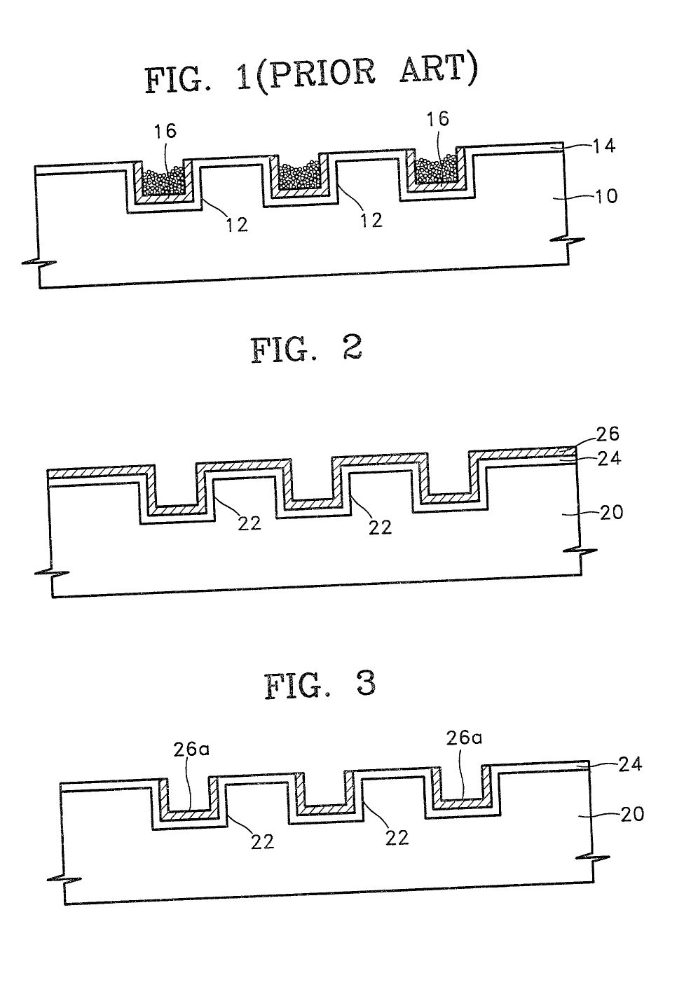

FIGS. 2 through 5 are sectional views for illustrating processes in manufacturing a copper metal interconnection using a solution for CMP according to an embodiment of the present invention.

### DETAILED DESCRIPTION OF THE INVENTION

The present invention now will be described more fully hereinafter with reference to the preferred embodiments of the invention, and drawings for illustrating the embodiments. This invention may, however, be embodied in many different forms and should not be construed as being limited to the embodiments set forth herein. Rather, these embodiments are provided so that this disclosure will be thorough and complete, and will fully convey the concept of the invention to those skilled in the art. The same reference numerals in different drawings represent the same elements.

According to a preferred embodiment of the present invention, a solution for CMP relates to a solution used for manufacturing a copper (Cu) metal interconnection, and more particularly, to a solution for CMP without an abrasive. That is, a conventional solution essentially includes an abrasive such as alumina (Al₂O₃) or silica (SiO₂), and the abrasive may remain within a wafer after CMP process, and the remaining abrasive may scratch the surface of the wafer. However, the solution according to a preferred embodiment of the present invention does not include the abrasive, thus avoiding the above problems caused by abrasive.

The solution for CMP according to a preferred embodiment of the present invention includes an oxidizing agent, a pH controlling agent, a chelate reagent, and deionized water.

The oxidizing agent is, preferably, hydrogen peroxide (H₂O₂), an oxidizing agent of a ferric series, or an oxidizing agent of an ammonium series. If hydrogen peroxide (H₂0₂) is used as the oxidizing agent, the hydrogen peroxide preferably has a concentration of about 1% to about 20% by weight, and more preferably, about 1% to about 10% by weight. If an oxidizing agent of the ferric series such as Fe(NO₃)₃ or Fe(PO₄)₃ is used, the oxidizing agent of the ferric series preferably has a concentration of about 0.01% to about 5% by weight, and more preferably, about 0.01% to about 1% by weight. If an oxidizing agent of the ammonium series such as NH₄NO₃ or NH₄H₂PO₄ is used, the oxidizing agent of the ammonium series preferably has a concentration of about 0.01% to about 5% by weight, and more preferably, about 0.01% to about 1% by weight.

According to a preferred embodiment of the present invention, the pH of the solution for CMP is preferably between about 2 and about 11. The pH of the solution is controlled with an acidic solution or a basic solution. As an acidic pH controlling agent, an acid solution such as sulfuric acid (H₂SO₄) solution, nitric acid (HNO₃) solution, hydrochloric acid (HCl) solution or phosphoric acid (H₃PO₄) solution may be used. As a basic pH controlling agent, a basic solution such as potassium hydroxide (KOH) solution or ammonium hydroxide (NH₄OH) solution may be used.

As the chelate reagent, citric acid, malic acid, gluconic acid, gallic acid, tannic acid, ethylenediaminetetraacetic acid (EDTA), benzotriazole (BTA), nitrilotriacetic acid (NTA), NHEDTA, DPTA or EDG may be used. The chelate reagent preferably has a concentration of about 0.001% to about 1% by weight, and more preferably, about 0.001% to about 0.1% by weight.

According to a preferred embodiment of the present invention, copper removal rate by the CMP is about 1000 Å/min through about 2000 Å/min, tantalum (Ta) removal rate by the CMP is about 200 Å/min through about 500 Å/min, tantalum nitride (TaN) removal rate by the CMP is about 200 Å/min through about 500 Å/min, and plasma enhanced tetraethyl ortho-silicate (PETEOS) is removed at a rate lower than about 50 Å/min.

Hereinafter, a manufacturing method of a metal interconnection using a solution for CMP process according to a preferred embodiment of the present invention will be described.

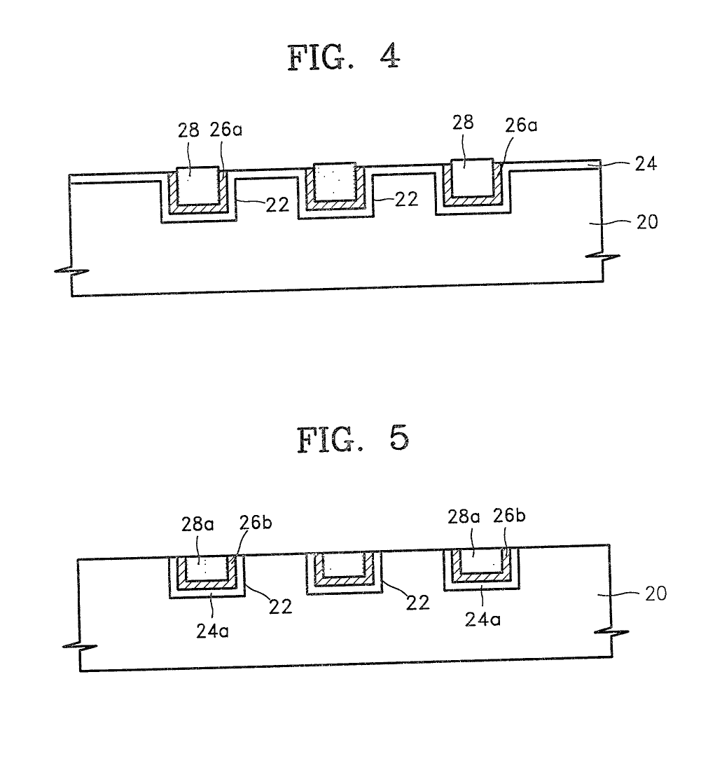

FIGS. 2 through 5 are sectional views illustrating processes in a method of manufacturing a copper metal interconnection using a solution for CMP process of the present invention.

Referring to FIG. 2, recessed regions 22 are formed on an interdielectric layer 20 which is formed on a semiconductor substrate (not shown) using a photolithography and an etching process. The recessed regions 22 may be trenches having a predetermined depth within the interdielectric layer 20, the recessed region 22 may be contact holes or via holes which penetrate the interdielectric layer 20 and expose a lower layer, or the recessed regions 22 may be a combination of trenches, contact holes and via holes. Hereinafter, an example in which the recessed regions 22 are trenches is described.

Then, a barrier layer 24 is formed along a stepped portion on the surface of the interdielectric layer 20 having the trenches. The barrier layer 24 is preferably formed of a material such as titanum (Ti), titanum nitride (TiN), tantalum (Ta) and tantalum nitride (TaN) which can prevent diffusion of a metal, and act as an adhesive layer between the interdielectric layer 20 and a metal interconnection to be formed.

Next, a copper (Cu) seed layer 26 is formed along a stepped portion on the barrier layer 24 using a physical vapor deposition (PVD) method such as sputtering.

Referring to FIG. 3, CMP is performed using the solution of the present invention to polish and remove the upper copper seed layer 26, and then, a trench copper seed layers 26a are formed in the recessed regions 22 where a metal interconnection is to be formed, and the surface of the barrier layer 24 except in the recessed regions 22 is exposed.

The conventional slurry solution including abrasives may leave abrasives in the trenches 22 where the interconnection will be formed after the CMP process, and causes problems such as contamination of a wafer, and more seriously, lifting of the interconnection. Also, the abrasive scratches the wafer. However, if the CMP process is performed using a solution without an abrasive according to the present invention, the problems of the conventional slurry, such as scratching of the wafer caused by abrasive and abrasive remaining within the trenches, do not exist.

Referring to FIG. 4, copper layers 28 are formed on the trench copper seed layers 26a by a normal electroplating process to fill the recessed region 22 Here, since the electroplating process is done only in the region where the trench copper seed layers 26a are formed, the copper layers 28 are formed within the recess regions 22.

Referring to FIGS. 4 and 5, portions of the copper layer 28 projecting above the surface of the interdielectric layer 20, portions of the trench copper seed layer 26a projecting above the surface of the interdielectric layer 20 and portions of the barrier layer 24 projecting above the surface of the interdielectric layer 20 are removed by second CMP process, and then, a copper metal interconnection layer 28a filling the recessed regions 22 is formed. And a planarized barrier layer 24a and a planarized trench copper seed layer 26b also are formed.

The advantageous of a solution for CMP and a manufacturing process of a copper metal interconnection layer using the solution according to the present invention include: first, since an abrasive in the CMP solution is not included, various defects such as contamination of the wafer by remaining abrasives or scratching by abrasives are removed or substantially entirely eliminated.

Second, since an abrasive is not included in the solution, the cost of manufacturing a CMP solution is reduced.

Third, since the copper layer is formed only within the recessed region where the interconnection is to be formed, it is not necessary for the copper layer to be thick. Thus, the required amount of CMP for forming the copper metal interconnection is largely reduced.

Fourth, since only a small amount of the copper layer is polished, uniformity of the surface of the wafer having copper metal interconnection layer is excellent. Also, since excessive CMP is not required, dishing or erosion of the interdielectric layer can be prevented.

This invention has been particularly described with reference to preferred embodiments thereof, however, it is not limited to the preferred embodiments and various changes may be made by those skilled in the art without departing from the spirit and scope of the invention as defined by the appended claims.

What is claimed is:

1. A solution for use in a chemical mechanical polishing process comprising an oxidizing agent, a pH controlling agent, a chelate reagent, and deionized water.

2. The solution of claim 1, wherein the solution is used for chemical mechanical polishing of a copper metal interconnection layer.

3. The solution of claim 1, wherein the oxidizing agent is hydrogen peroxide (H₂O₂), an oxidizing agent of a ferric series or an oxidizing agent of an ammonium series.

4. The solution of claim 3, wherein the concentration of hydrogen peroxide is within the range of about 1 % to about 20% by weight.

5. The solution of claim 3, wherein the concentration of the oxidizing agent of the ferric series is within the range of about 0.01 % to about 5% by weight.

6. The solution of claim 3, wherein the concentration of the oxidizing agent of the ammonium series is within the range of about 0.01% to about 5% by weight.

7. The solution of claim 1, wherein a pH of the solution is within the range of about 2 to about 11.

8 The solution of claim 1, wherein the pH controlling agent is an acidic or a basic solution.

9 The solution of claim 8, wherein the acidic solution is a sulfuric acid solution, a nitric acid solution, a hydrochloric acid solution or a phosphoric acid solution, and the basic solution is a potassium hydroxide solution or an ammonium hydroxide solution.

10. The solution of claim 1, wherein the chelate reagent is diammonium sodium salt (DASS), citric acid, malic acid, gluconic acid, gallic acid, tannic acid, ethylenediaminetetraacetic (EDTA) or benzotriazole (BTA).

11 The solution of claim 1, wherein the concentration of the chelate reagent is within the range of about 0.001% to 1% by weight.

12. A method of manufacturing a copper metal interconnection layer comprising the steps of:
(a) forming a barrier layer along a stepped portion over the surface of an interdielectric layer having a recessed region;
(b) forming a copper seed layer on the barrier layer; and
(c) exposing the barrier layer until exposing the surface of the interdielectric layer by chemical mechanical polishing using a solution comprising an oxidizing agent, a pH controlling agent, a chelate reagent, and deionized water so that the copper seed layer remains only within the recessed region.

13 The method of claim 12, after the step (c), further comprising the steps of:
forming a copper layer on the copper seed layer formed in the recessed region; and
forming a copper metal interconnection layer by planarizing the copper layer projecting above the surface of the interdielectric layer, the copper seed layer projecting above the surface of the interdielectric layer and the barrier layer projecting above the surface of the interdielectric layer.

14. The method of claim 12, wherein the recessed region includes a trench region in the shape of a line recessed from the surface of the interdielectric layer.

15. The method of claim 12, wherein the recessed region includes a combination of a trench region in the shape of a line recessed from the surface of the interdielectric layer, and contact holes or via holes penetrating the interdielectric layer.

16. The method of claim 12, wherein the barrier layer is formed using a material which can prevent diffusion of metal and act as an adhesive layer between the interdielectric layer and the metal interconnection.

17. The method of claim 12, wherein in the step (b), the copper seed layer is formed by a physical vapor deposition method.

18. The method of claim 12, wherein the oxidizing agent is hydrogen peroxide, an oxidizing agent of a ferric series or an oxidizing agent of an ammonium series.

19. The method of claim 18, wherein the concentration of hydrogen peroxide is within the range of about 1% to about 20% by weight.

20. The method of claim 18, wherein the concentration of the oxidizing agent of the ferric series is within the range of about 0.01% to about 5% by weight.

21. The method of claim 18, wherein the concentration of the oxidizing agent of the ammonium series is within the range of about 0.01% to about 5% by weight.

22. The method of claim 12, wherein a pH of the solution is within the range of about 2 to about 11.

23. The method of claim 12, wherein the pH controlling agent is an acidic or a basic solution.

24. The method of claim 23, wherein the acidic solution is a sulfuric acid, a nitric acid, a hydrochloric acid or a phosphoric acid solution, and the basic solution is a potassium hydroxide or an ammonium hydroxide solution.

25. The method of claim 12, wherein the chelate reagent is diammonium sodium salt (DASS), citric acid, malic acid, gluconic acid, gallic acid, tannic acid, ethylenediaminetetraacetic (EDTA) or benzotriazole (BTA).

26. The method of claim 12, wherein the concentration of the chelate reagent is within the range of about 0.001% to about 1% by weight.

27. A solution for use in a chemical mechanical polishing process consisting essentially of an oxidizing agent, a pH controlling agent, a chelate reagent, and deionized water.
